(19) United States
(12) Patent Application Publication
(10) Pub. No.: US 2014/0372051 A1
(43) Pub. Date: Dec. 18, 2014

(54) ESTIMATING METHOD AND ESTIMATING SYSTEM OF INSULATION LIFETIME

(71) Applicant: HITACHI METALS, LTD., Tokyo (JP)

(72) Inventor: Yosuke SUMI, Hitachi-shi (JP)

(73) Assignee: HITACHI METALS, LTD., Tokyo (JP)

(21) Appl. No.: 14/265,564

(22) Filed: Apr. 30, 2014

(30) Foreign Application Priority Data
Jun. 17, 2013 (JP) 2013-126478

(51) Int. Cl. G01R 31/02

(52) U.S. Cl. CPC G01R 31/025
USPC 702/58

(57) ABSTRACT

There is provided an estimating method of an insulation lifetime for estimating an insulation lifetime in a sample constituted by including a conductor and an insulator, including: an information acquisition step (S2) of obtaining correlative information regarding a discharged electric charge amount caused by a partial discharge in the sample and an insulation breakdown of the sample; an electric charge amount detection step (S3) of generating a partial discharge in the sample in the stage of estimating the insulation lifetime and detecting a discharged electric charge amount caused by the partial discharge; and a lifetime estimation step (S4) of obtaining a period until the insulation breakdown occurs in the sample, from the discharged electric charge amount detected in the electric charge amount detection step, based on the correlative information obtained in the information acquisition step (S2), as a estimation result of the insulation lifetime.

The present application is based on Japanese Patent Application No. 2013-126478 filed on Jun. 17, 2913, the entire contents of which are hereby incorporated by reference.

### BACKGROUND

1. Technical Field

The present invention relates to an estimating method and an estimating system of an insulation lifetime.

2. Description of Related Art

An electric wire such as an enamel wire is configured to include an insulator (insulation coating) so as to surround a circumference of a conductor. The electric wire configured to include a conductor and an insulator, generates a partial discharge in some cases depending on its use condition or use environment, etc. The partial discharge is a state that a feeble electric sparking (discharging phenomenon) is generated in the insulator or in a minute void (gap) between the conductor and the insulator. When the partial discharge is generated, the electric wire involves a risk of an insulation breakdown in which the insulator is broken, thereby not maintaining an insulation state. Therefore, estimation of a period until the insulation breakdown occurs in the insulator (namely insulation lifetime) is generally performed for the electric wire in a probable use condition and use environment, etc.

As an estimating method of the insulation lifetime of the electric wire, it is generally performed to utilize V-t (V: applied voltage, t: breakdown time) characteristic of the electric wire. However, in recent years, an inverter power supply is frequently used as a power supply for motors for example, and therefore an abrupt incoming of an overvoltage (inverter surge voltage) into the electric wire occurs in some cases, and such a situation is required to be taken into consideration. Therefore, conventionally there is an estimating method of an insulation lifetime in which the insulation lifetime can be estimated even under application of the inverter surge voltage, by shift of the V-t characteristic under AC voltage to the V-t characteristic under inverter surge voltage by an addition of PDIV under inverter surge voltage to a partial discharge inception voltage (called “PDIV” hereafter) under AC voltage (for example, see patent document 1).

Patent document 1: Japanese Patent Laid Open Publication No. 1997-80006

### SUMMARY OF THE INVENTION

It can be considered that the insulation lifetime of the electric wire is controlled (influenced) by the partial discharge and the particle discharge is influenced by an applied voltage waveform condition (such as rise time and pulse width, etc.). For example, PDIV is influenced by the rise time of the waveform of the applied voltage under inverter surge voltage. Thus, a generation mode of the partial voltage that influences the insulation lifetime can be different depending on the applied voltage waveform condition.

However, in the estimating method of an insulation lifetime utilizing the conventional V-t characteristic, the period until the insulation breakdown occurs is measured by continuously applying the voltage of a fixed peak value to the electric wire under constant applied voltage waveform condition in a V-t test which is performed beforehand, and based on a result thereof, the insulation lifetime of the electric wire in practical use is estimated. Namely, although the applied voltage waveform condition is different in real time and a voltage value is varied in real time in practical use, the influence of the applied voltage waveform condition in the practical use is not taken into consideration for the estimation result of the insulation lifetime of the electric wire in the practical use. Probably this is remarkable particularly under the inverter surge voltage. Therefore, there would be no sufficient reliability in the estimation result of the insulation lifetime in a case of the conventional estimating method of an insulation lifetime.

In this point, for example it can be considered that the V-t test is conducted so as to meet variously estimated applied voltage waveform conditions, and the V-t test is conducted every time the applied voltage waveform condition is changed in the practical use. However, it is not efficient to conduct the V-t test every time the applied voltage waveform condition is changed.

Further, as the conventional estimating method of an insulation lifetime, there is a method in consideration of an applied inverter surge voltage as shown in patent document 1. However, since there is a necessity for converting the V-t characteristic by PDIV ratio, and this method is not efficient because the conversion of the V-t characteristic is required.

Therefore, an object of the present invention is to provide the estimating method and the estimating system of an insulation lifetime capable of efficiently estimating an insulation lifetime by estimating the insulation lifetime in consideration of the influence of the applied voltage waveform condition and even in this case, capable of efficiently estimating the insulation lifetime while improving reliability in the estimation result of the insulation lifetime.

In order to achieve the above-mentioned object, the present invention is provided, and according to an aspect of the present invention, there is provided an estimating method of an insulation lifetime for estimating an insulation lifetime in a sample constituted by including a conductor and an insulator, including:

an information acquisition step of obtaining correlative information regarding a discharged electric charge amount caused by a partial discharge in the sample and an insulation breakdown of the sample;

an electric charge amount detection step of generating a partial discharge in the sample in the stage of estimating the insulation lifetime and detecting a discharged electric charge amount caused by the partial discharge; and

a lifetime estimation step of obtaining a period until the insulation breakdown occurs in the sample, from the discharged electric charge amount detected in the electric charge amount detection step, based on the correlative information obtained in the information acquisition step, as a estimation result of the insulation lifetime.

According to other aspect of the present invention, there is provided an estimating system of an insulation lifetime for estimating an insulation lifetime in a sample constituted by including a conductor and an insulator, including:

an information acquisition section configured to obtain correlative information regarding a discharged electric charge amount caused by a partial discharge in the sample and an insulation breakdown of the sample;

an electric charge amount detection section configured to detect a discharged electric charge amount caused by a partial discharge by generating the partial discharge in the sample in the stage of estimating the insulation lifetime; and

a lifetime estimation section configured to obtain a period until an insulation breakdown occurs in the sample, from a discharged electric charge amount detected by the electric charge amount detection section, based on the correlative information obtained by the information acquisition section, and obtain a estimation result of the insulation lifetime.

### BRIEF DESCRIPTION OF THE DRAWINGS

FIG. 1 is a block diagram showing a schematic constitutional example of an estimating system of an insulation lifetime according to an embodiment of the present invention.

FIG. 2 is a flowchart showing an outline of a procedure of an estimating method of an insulation lifetime according to an embodiment of the present invention.

FIG. 3 is a schematic view showing a specific example of a circuit structure of the estimating system of an insulation lifetime according to an embodiment of the present invention.

FIG. 4 is an explanatory view showing a specific example of voltage data (waveform data) recorded in a data logger of the estimating system of an insulation lifetime according to an embodiment of the present invention.

FIG. 5 is an explanatory view showing an expanded view of a part of the voltage data (waveform data) recorded in the data logger of the estimating system of an insulation lifetime according to an embodiment of the present invention.

FIG. 6 is a flowchart showing an outline of a processing procedure of an advance preparation step according to an embodiment of the present invention.

FIG. 7 is an explanatory view showing a specific example of correlative information according to an embodiment of the present invention.

FIG. 8 is a flowchart showing an outline of a processing procedure of an electric charge amount detection step according to an embodiment of the present invention.

FIG. 9 is an explanatory view showing a specific example of correlative information according to other embodiment of the present invention.

### DETAILED DESCRIPTION OF THE INVENTION

An embodiment of the present invention will be described hereafter, based on the drawings.

Explanation is given here for each item in the following order.

### 1. Outline

2. An embodiment

2-1. Outline structure of an estimating system of an insulation lifetime

2-2. Procedure of an estimating method of an insulation lifetime

3. Other embodiment
4. Effect of each embodiment
5. Modified example, etc.

### 1. Outline

First, the estimating method and the estimating system of an insulation lifetime of the present invention will be described.

The present invention is the invention of estimating an insulation lifetime of an electric wire, etc., generating a partial discharge. The term of “electric wire, etc.” used here includes the electric wire having a conductor and an insulator other than an electric wire such as an enamel wire. The “partial discharge” means a feeble discharging phenomenon in which insulation deterioration is caused in the insulator of an electric wire, etc. The “insulation lifetime” means a period from start of usage of the electric wire, etc., until insulation breakdown occurs in the electric wire, etc., due to the insulation deterioration, thereby not maintaining an insulation state.

After strenuous efforts of inventors of the present invention regarding the partial discharge and the insulation deterioration of the insulator in providing the present invention, it is found that there is a correlation between the partial discharge and the insulation deterioration. More specifically, the following knowledge is obtained: namely, there is a fixed relation between the electric charge amount of the partial discharge generated in the electric wire, etc., (called “discharged electric charge amount” hereafter), and a volume of the insulator eroded by the insulation deterioration due to the partial discharge, and such a relation is established even if the applied voltage waveform condition for the electric wire, etc., is changed (for example, even under inverter surge voltage). Based on this knowledge, as a result of further strenuous efforts by the inventors of the present invention, a concept regarding a new unconventional technique of evaluating a lifetime can be obtained, which is the concept that the insulation lifetime of the electric wire, etc., is estimated using the discharged electric charge amount as an index. The present invention is achieved based on such a new concept by the inventors of the present invention.

According to the estimating method and the estimating system of an insulation lifetime of the present invention, the insulation lifetime of the electric wire, etc., is estimated by the procedure described below.

Specifically, the correlative information regarding the discharged electric charge amount caused by the partial discharge in the sample and the insulation breakdown of the sample, is previously specified, in which the sample is the electric wire, etc., which is an estimation object of the insulation lifetime. The term of “correlative information” used here is the information for specifying the relation between the discharged electric charge amount and the insulation breakdown, which is the information regarding a total discharged electric charge amount Q_{B.D} causing the insulation breakdown and an aging variation characteristic of the discharged electric charge amount resulting in the insulation breakdown to occur as described later in detail. Such correlative information is preferably specified by measuring the discharged electric charge amount described later in detail. Further, it can be considered that a database section is constructed and the specified correlative information is stored and held in the database section.

Thereafter, in the stage of estimating the insulation lifetime, the correlative information regarding the sample is retrieved from the database section, and the partial discharge is generated in the sample, and the discharged electric charge amount caused by the partial discharge actually generated in the sample, is detected. Detection of the discharged electric charge amount is preferably performed as follows: the partial discharge is generated by applying a voltage to the sample so as to exceed PDIV for a previously set specific time, and the discharged electric charge amount caused by the partial discharge is detected using a residual voltage detection circuit by a residual electric charge method for example. Namely, the term of “actually” used here, is the meaning of actually detecting the discharged electric charge amount when the partial discharge is actually generated in the stage of estimating the insulation lifetime.

After the discharged electric charge amount is detected, the detected discharged electric charge amount is compared with the correlative information the result of which is acquired to thereby obtain the period until the insulation breakdown occurs in the sample based on the correlative information, and obtain an estimation result of the insulation lifetime of the sample. Thus, for example, when the correlative information is the information for specifying a total discharged electric charge amount Q_{B.D.}, as described later in detail, a lifetime term until the insulation breakdown occurs in the sample, is estimated from the discharged electric charge amount in an initial stage of using the sample. Further, for example, when the correlative information is the information for specifying the aging characteristics of the discharged electric charge amount, as described later in detail, a remaining lifetime term of the sample is estimated from the discharged electric charge amount in the sample after elapse of a certain charging time.

As described above, the estimating method and the estimating system of an insulation lifetime according to the present invention, employs a technique of estimating the insulation lifetime of the sample using the discharged electric charge amount caused by the partial discharge of the sample as an index. Namely, by using the discharged electric charge amount of the partial discharge in a correlative relation with the insulation breakdown of the insulator as the index of estimating an insulation lifetime, the insulation lifetime is estimated based on not the applied voltage but the actually generated discharged electric charge amount. Therefore, the insulation lifetime can be estimated in consideration of an influence of a rise time of variously different applied voltage waveforms. Accordingly, according to the estimating method and the estimating system of an insulation lifetime of the present invention, the insulation lifetime can be estimated in consideration of the influence of the applied voltage waveform condition, and therefore even in this case, the insulation lifetime can be efficiently estimated while improving reliability in the estimation result of an insulation lifetime.

### 2. An Embodiment

An embodiment of the present invention will be described next.

### [2-1. Outline Structure of an Estimating System of an Insulation Lifetime]

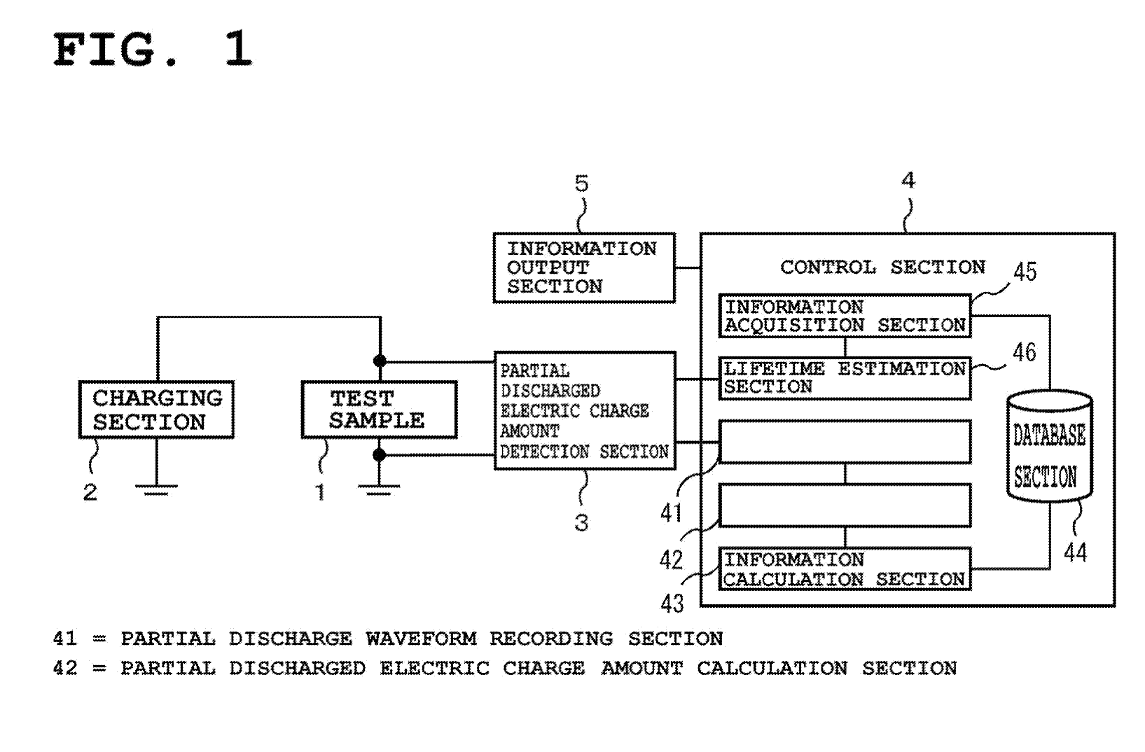

FIG. 1 is a block diagram showing an example of an outline structure of an estimating system of an insulation lifetime according to an embodiment of the present invention.

The estimating system of an insulation lifetime of this embodiment is configured to estimate the insulation lifetime of sample 1 for testing, wherein the sample 1 is disposed between a charging section 2 and a ground (ground connection). Sample 1 may be configured to include a conductor and an insulator. For example an electric wire such as enamel wire, twist wire, twist pair wire (twist pair cable), etc., can be tested as sample 1.

In order to estimate the insulation lifetime of such a sample 1, the estimating system of an insulation lifetime of this embodiment, includes a charging section 2, a partial discharged electric charge amount detection section 3, a control section 4, and an information output section 5, if broadly classified.

The charging section 2 is configured to apply higher voltage to sample 1, which is higher than PDIV of the sample 1, so that partial discharge is generated in the sample 1. Application of the voltage by the charging section 2 can be performed by inverter surge pulse, and can also be performed by AC voltage or impulse voltage. The charging section 2 thus configured to apply voltage, may be constituted using a publicly-known voltage application device such as an inverter pulse generator or a surge pulse generator, etc.

The partial discharged electric charge amount detection section 3 is configured to detect the discharged electric charge amount at the time of generating the partial discharge, regarding the sample 1 generating the partial discharge. As will be described later in detail, detection of the discharged electric charge amount is performed utilizing a residual electric charge method using a serial capacitor. However, the present invention is not limited thereto, and the discharged electric charge amount may be detected for example by measuring a discharge current/voltage waveform by a differential detection method using a high frequency CT, or a detection impedance method, etc.

The control section 4 is configured to perform processing required for estimating the insulation lifetime of sample 1. The required processing includes advance preparation processing for estimating the insulation lifetime, and lifetime estimation processing for actually estimating the insulation lifetime, if broadly classified. The control section 4 has a function as a partial discharge waveform recording section 41, a partial discharged electric charge amount calculation section 42, an information calculation section 43, and a database section 44, for performing the advance preparation processing. Also, the control section 4 has a function as an information acquisition section 45 and a lifetime estimation section 46 for performing lifetime estimation processing.

The partial discharge waveform recording section 41 is configured to record waveform data continuously without missing, which is a detection result of the discharged electric charge amount detected by the partial discharged electric charge amount detection section 3, for a long time from the start of usage until the insulation breakdown occurs, regarding the same kind of sample 1 as the sample 1 whose insulation lifetime is supposed to be estimated later.

The partial discharged electric charge amount calculation section 42 is configured to calculate the discharged electric charge amount per 1 pulse of waveform data and cumulatively add the discharged electric charge amount from the start of usage until the insulation breakdown occurs, by processing the waveform data recorded in the partial discharge waveform recording section 41, using a specific calculation program.

The information calculation section 43 is configured to generate the correlative information regarding the sample 1 whose discharged electric charge amount is detected by the partial discharge waveform recording section 41, based on a calculation result obtained by the partial discharged electric charge amount calculation section 42. Specifically, the information calculation section 43 is configured to generate a cumulative value of the discharged electric charge amount, namely the total discharged electric charge amount Q_{B.D.} [unit: C] required from start of usage until the insulation breakdown occurs, which is the calculation result obtained by the partial discharged electric charge amount calculation section 42, as the correlative information, and store and hold the correlative information in the database section 44.

The database section 44 is configured to store and hold the correlative information generated by the information calculation section 43, in association with the kind of the sample 1 whose correlative information is obtained.

The information acquisition section 45 is configured to read and acquire the correlative information regarding the same kind of sample 1 as the sample 1 for testing, stored and held in the database section 44, namely the information for specifying the total discharged electric charge amount Q_{B.D.} until the insulation breakdown occurs in the sample 1, from the database section 44, for estimating the insulation lifetime of the sample 1 for testing.

The lifetime estimation section 46 is configured to obtain the period until the insulation breakdown occurs in sample 1, from the discharged electric charge amount detected by the partial discharged electric charge amount detection section 3, based on the correlative information obtained by the information acquisition section 45, and obtain the estimation result of the insulation lifetime of the sample 1. More specifically, since the information acquisition section 45 acquires the information for specifying the total discharged electric charge amount Q_{B.D}, the lifetime estimation section 46 obtains the period from the start of usage of the sample 1 until the insulation breakdown occurs in the sample 1, by dividing the total discharged electric charge amount Q_{B.D} by the discharged electric charge amount per unit time detected by the partial discharged electric charge amount detection section 3 as will be described later in detail.

It can be considered that the control section 4 having the function as each section 41 to 46, is realized by utilizing a computer device that executes a specific program. Namely, the control section 4 is formed by the computer device composed of a combination of CPU (Central Processing Unit), RAM (Random Access Memory), and HDD (Hard disk drive), etc. In this case, the computer device may be a single set or may be multiple sets connected to each other via a communication line. In a case of the multiple sets, the above-mentioned function as each section 41 to 46 may be dispersed to the multiple sets.

The information output section 5 is composed of a display, etc., connected to the control section 4, and is configured to output information regarding a processing result performed by the control section 4. The information regarding the estimation result of the insulation lifetime regarding sample 1, can be given as the information outputted by the information output section 5.

### [2-2. Procedure of the Estimating Method of an Insulation Lifetime]

Subsequently, explanation is given for a procedure of the estimating method of an insulation lifetime performed using the estimating system of an insulation lifetime having the above-mentioned structure.

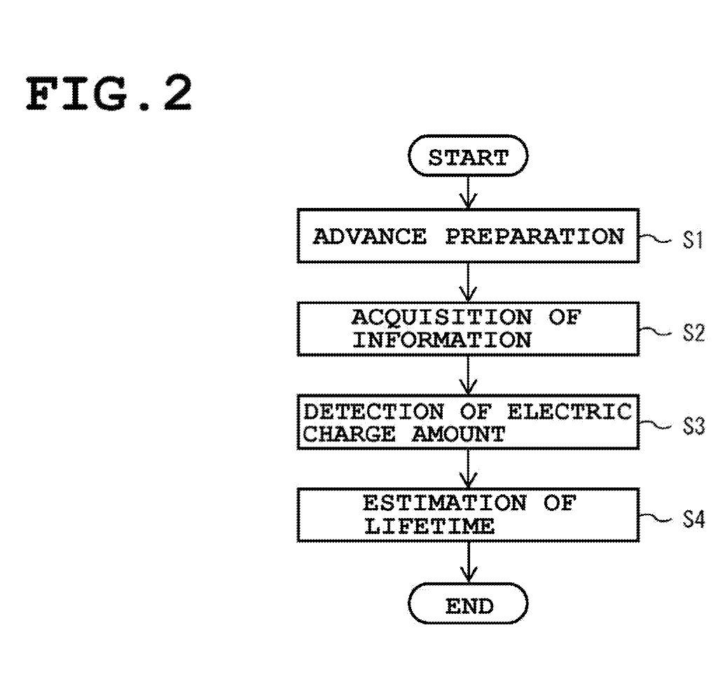

FIG. 2 is a flowchart showing an outline of the procedure of the estimating method of an insulation lifetime according to this embodiment.

In the estimating method of an insulation lifetime according this embodiment, the insulation lifetime of the sample 1 for testing is estimated through the steps of advance preparation step (S1), information acquisition step (S2), electric charge amount detection step (S3), and lifetime estimation step (S4) sequentially. Each step of them (S1 to S4) will be sequentially described hereafter.

### (S1: Advance Preparation Step)

Advance preparation step (S1) is the step of continuously detecting the discharged electric charge amount caused by the partial discharge from the start of usage until the insulation breakdown occurs for the same kind of sample 1 as the sample 1 for testing, thereby generating the correlative information from the detection result thereof, and storing and holding the correlative information in the database section 44.

### (Circuit Structure of the Estimating System of an Insulation Lifetime)

Here, explanation is given for a specific circuit structure of the estimating system of an insulation lifetime used for performing the advance preparation step (S1), using a case of utilizing the residual electric charge method as an example.

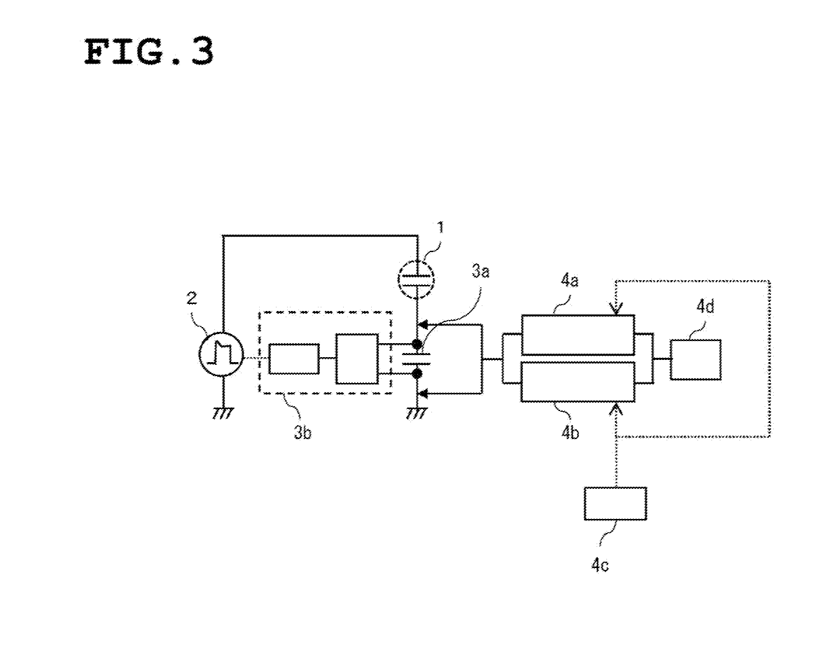

FIG. 3 is a schematic view showing a specific circuit structure of the estimating system of an insulation lifetime according this embodiment. In the figure, the same signs and numerals are assigned to the same constitutional elements as shown in FIG. 1.

In the estimating system of an insulation lifetime shown in the figure, a higher voltage than PDIV of the sample 1 is applied to the sample 1 from the charging section 2 by the inverter surge pulse for example. At this time, the sample 1 to which the inverter surge pulse is applied, is the same kind as the sample 1 whose insulation lifetime is supposed to be estimated later.

Further, a capacitor 3a constituting a part of the partial discharged electric charge amount detection section 3 is connected to the sample 1 in series between the sample 1 and the ground (ground connection). The capacitor 3a is provided for storing an electric charge caused by generation of the partial discharge in the sample 1. Therefore, the capacitor having a larger electrostatic capacity than the electrostatic capacity of sample 1, is used as the capacitor 3a, so that the voltage is mostly applied to the sample 1.

A short circuit (refresh circuit) 3b constituting a part of the partial discharged electric charge amount detection section 3, is connected to both ends of the capacitor 3a. The short circuit 3b is configured to cause discharge by short-circuiting both ends of the capacitor 3a to periodically refresh excessive accumulation of the electric charge in the capacitor 3a. Therefore, the short circuit 3b is configured to output a drive pulse (for example, 1 ms width) after elapse of a specific time from rise of the pulse, so as to be synchronized with the inverter pulse outputted by the charging section 2, and short-circuit the both ends of the capacitor 3a by operating relay.

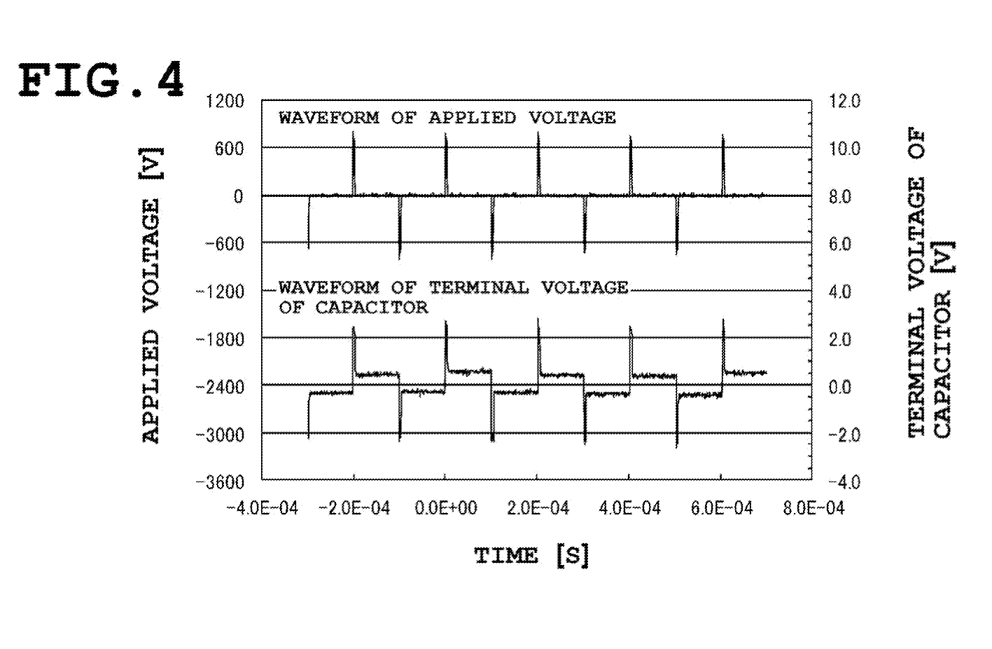

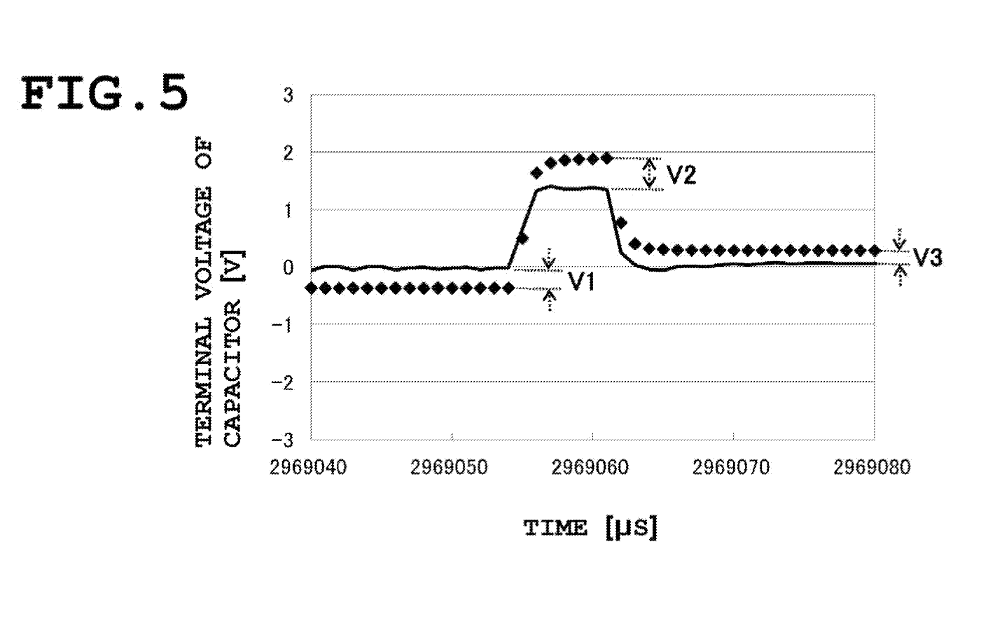

Further, a plurality of data loggers 4a, 4b (for example two data loggers) constituting a part of the partial discharge waveform recording section 41, are connected to the both ends of the capacitor 3a. Both data loggers 4a, 4b are configured to measure a terminal voltage of the capacitor 3a, and record the measured voltage in the form of waveform data, etc., for example. Thus, the terminal voltage of the capacitor 3a is recorded in each data logger 4a, 4b in the form of the waveform data as shown in FIG. 4 and FIG. 5 for example. Here, FIG. 4 shows a specific example of the voltage data (waveform data) recorded in the data logger, and FIG. 5 is an expanded view showing a part of the voltage data (waveform data) recorded in the data logger.

A plurality of data loggers 4a, 4b are used together, for recording all data without generating the missing of data, by selectively operating the data loggers 4a, 4b while overlapping each of them respectively, even when data recording is performed for a long time from start of usage until the insulation breakdown occurs. Namely, by using a plurality of data loggers 4a, 4b together, one of the data loggers 4a, 4b (for example data logger 4b) can perform recording of the waveform data while time is required for outputting and transmitting recording data by the other data logger 4a for example.

Thus, since a plurality of data loggers 4a, 4b are used together, as shown in FIG. 3, a timer mechanism 4c constituting a part of the partial discharge waveform recording section 41, is connected to each data logger 4a, 4b. The timer mechanism 4c is configured to monitor a specific time (for example 10 seconds) for switching an operation of the data loggers 4a, 4b, and switch an operation instruction given to the data loggers 4a, 4b in each specific time.

Further, a controller 4d that functions as the partial discharged electric charge amount calculation section 42 and the information calculation section 43, is electrically connected to the data loggers 4a, 4b. Then, voltage data (waveform data) recorded in each data logger 4a, 4b is transmitted to the controller 4d at a specific timing.

When the data is transmitted from the data loggers 4a, 4, the controller 4d is configured to calculate the discharged electric charge amount, calculate an accumulated value of the discharged electric charge amount, and generate the correlative information based on calculation results of the discharged electric charge amount and the accumulated value, etc., of the discharged electric charge amount, by executing the specific program in which a procedure for calculating the discharged electric charge amount and a procedure for calculating the cumulative value of the discharged electric charge amount are described. Specifically, the controller 4d calculates the residual voltage caused by the partial discharge from a difference of a detected capacitor terminal voltage between before and after generating the partial discharge, to thereby obtain a product of the capacitance of the capacitor and the residual voltage as the discharged electric charge amount. Further, the controller 4d calculates the electric charge amount every one pulse, and calculates and accumulates the electric charge amount until the insulation breakdown occurs in the sample 1. The specific program executed by the controller 4d for the above calculations, may be realized utilizing a publicly-known technique, and in a case of calculating the discharged electric charge amount for example, VBA

(Visual Basic for Applications) program can be used.

### (Processing Procedure of the Advance Preparation Step)

Subsequently, a processing procedure of the advance preparation step (S1) will be described.

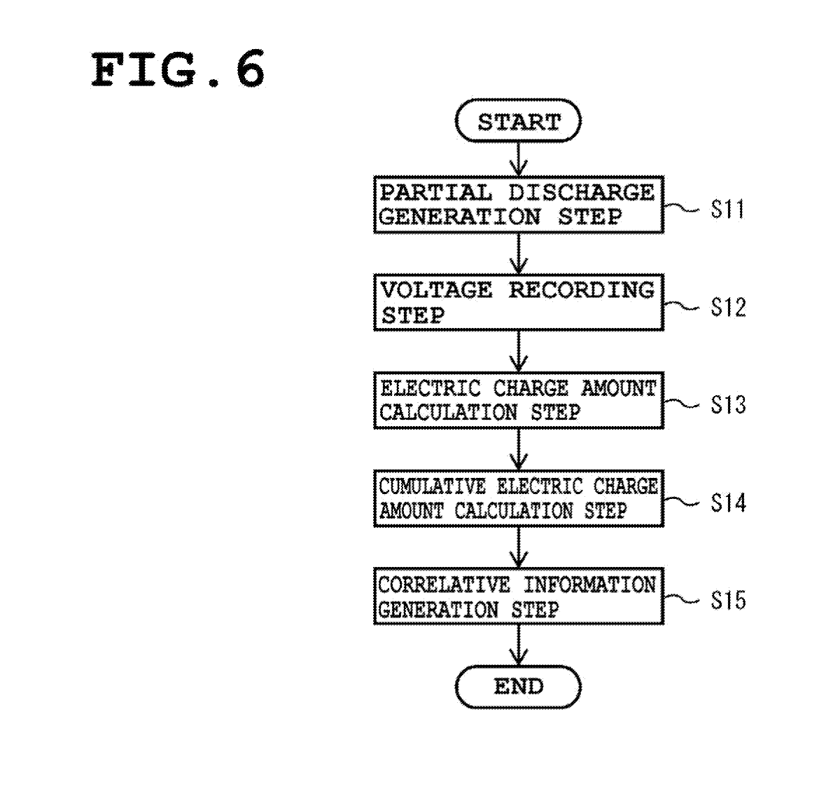

FIG. 6 is a flowchart showing an outline of the processing procedure of the advance preparation step according to this embodiment.

The advance preparation step (S1) includes the steps of partial discharge generation step (S11), voltage recording step (S12), electric charge amount calculation step (S13), cumulative electric charge amount calculation step (S14), and correlative information generation step (S15) sequentially.

### (Partial Discharge Generation Step)

In the partial discharge generation step (S11), the higher voltage than PDIV of the sample 1 is applied to the same kind of sample 1 as the sample 1 whose insulation lifetime is supposed to be estimated later, by the inverter surge pulse for example by the charging section 2, to thereby generate the partial discharge in the sample 1. The voltage is continuously applied to the sample 1 by the charging section 2, until it is confirmed that the insulation breakdown occurs in the sample 1.

### (Voltage Recording Step)

In the voltage recording step (S12), the operation of the data loggers 4a, 4b are started simultaneously with start of applying the voltage to the sample 1 by the charging section 2, to thereby measure and record the terminal voltage of the capacitor 3a. Then, the data loggers 4a, 4b are alternately operated at predetermined intervals while following a monitor result by the timer mechanism 4c, and the voltage outputted from the sample 1 is measured until the insulation breakdown occurs at least in the sample 1, and voltage data is recorded. Namely, the terminal voltage of the capacitor 3a is continuously measured and recorded from start of usage of the sample 1 until the insulation breakdown occurs in the sample 1.

When the operations of the data loggers 4a, 4b are switched, each data logger 4a, 4b is preferably operated together for a specific time. Namely, when the data loggers 4a, 4b are switched, preferably a plurality of data loggers 4a, 4b have a period in which they are operated together. Thus, if the data loggers 4a, 4b are simultaneously operated for a specific period, missing of recording data can be suppressed, when the data of the terminal voltage of the capacitor 3a is continuously recorded.

When the data of the terminal voltage of the capacitor 3a is recorded, thereafter the data loggers 4a, 4b transmit the recorded data to the controller 4d in the form of waveform data. Specifically, each data logger 4a, 4b transmits the data of the voltage recorded by a single operation, to the controller 4d as one file for example, in a period from stop of the operation to star of the operation. At this time, the transmitted data is preferably attached with information for specifying which of the data loggers 4a, 4b is used for recording the data. Further, the data transmitted to the controller 4d may also be attached with time information.

When excessive electric charge is accumulated in the capacitor 3a, the short circuit 3b connected to both ends of the capacitor 3a is operated, to short-circuit the both ends of the capacitor 3a and cause discharge. Preferably, for example, the short circuit 3b is operated at predetermined intervals from start of applying the voltage to the sample 1 by the charging section 2. Thus, accumulation of the excessive electric charge in the capacitor 3a can be suppressed, and therefore the voltage added on the capacitor 3a can be accurately measured.

### (Electric Charge Amount Calculation Step)

In the electric charge amount calculation step (S13), when the data transmitted from the data loggers 4a, 4b is received, the controller 4d calculates the electric charge amount remained in the capacitor 3a as the discharged electric charge amount discharged from the sample 1, based on the transmitted data. Specifically, the controller 4d recognizes the difference of the terminal voltage of the capacitor 3a, between before and after generating the partial discharge in the sample 1, based on the received transmitted data. Then, based on the Coulomb's law, the recognized difference of the terminal voltage of the capacitor 3a is multiplied by the electrostatic capacity of the capacitor 3a, to thereby calculate the electric charge amount remained in the capacitor 3a, and a calculation result thereof is regarded as the discharged electric charge amount discharged from the sample 1.

Here, a case that the voltage data shown in FIG. 5 is transmitted to the controller 4d, is considered. Note that the solid line in FIG. 5 indicates the terminal voltage of the capacitor 3a when the partial discharge is not generated, and the dot line in FIG. 5 indicates the terminal voltage of the capacitor 3a when the partial discharge is generated. In this case, the controller 4d calculates the discharged electric charge amount discharged from the sample 1, using the following formula (1).

Q=Cd×(|V2−V1|+|V3−|) (1)

Wherein in formula (1), Q indicates the discharged electric charge amount (residual electric charge amount in the capacitor 3a) discharged from the sample 1, and Cd indicates the electrostatic capacity of the capacitor 3a, and V1, V2, V3 respectively indicates the value of the difference of the terminal voltage of the capacitor 3a, between a case that the partial discharge is generated, and a case that the partial discharge is not generated.

At this time, it can be considered that the controller 4d calculates the discharged electric charge amount in every single operation period of the data loggers 4a, 4b (namely every time when the switch of the operation is generated). Namely, it can be considered that the controller 4d calculates the discharged electric charge amount every time a file is transmitted from the data loggers 4a, 4b.

When the data loggers 4a, 4b are simultaneously operated for a specific time, the controller 4d subtracts the voltage in the period when such a simultaneous operation is performed, from an overlapped portion, when calculating the discharged electric charge amount.

When the discharged electric charge amount is thus calculated, the controller 4d temporarily stores the calculation result in RAM, etc., which can be accessed by the controller 4d.

### (Cumulative Electric Charge Amount Calculation Step)

In the cumulative electric charge amount calculation step (S14), a cumulative discharged electric charge amount is calculated by the controller 4d, by cumulatively adding the discharged electric charge amount in each transmitted file calculated in the electric charge amount calculation step (S13), in the period from start of usage of the sample 1 until the insulation breakdown occurs. Namely, the controller 4d accumulates the discharged electric charge amount described in all files until the insulation breakdown occurs in the sample 1. Thus, a total amount of the discharged electric charge amount (called “total discharged electric charge amount” hereafter) until the insulation breakdown occurs in the sample 1 by generation of the partial discharge, can be calculated.

### (Correlative Information Generation Step)

In the correlative information generation step (S15), the controller 4d generates the correlative information based on the discharged electric charge amount calculated in the electric charge amount calculation step (S13) and the total discharged electric charge amount calculated in the cumulative electric charge amount calculation step (S14). Specifically, the controller 4d generates the cumulative value of the discharged electric charge amount which is a calculation result in the cumulative electric charge amount calculation step (S14), as the total discharged electric charge amount Q_{B.D.} which is a specific example of the correlative information.

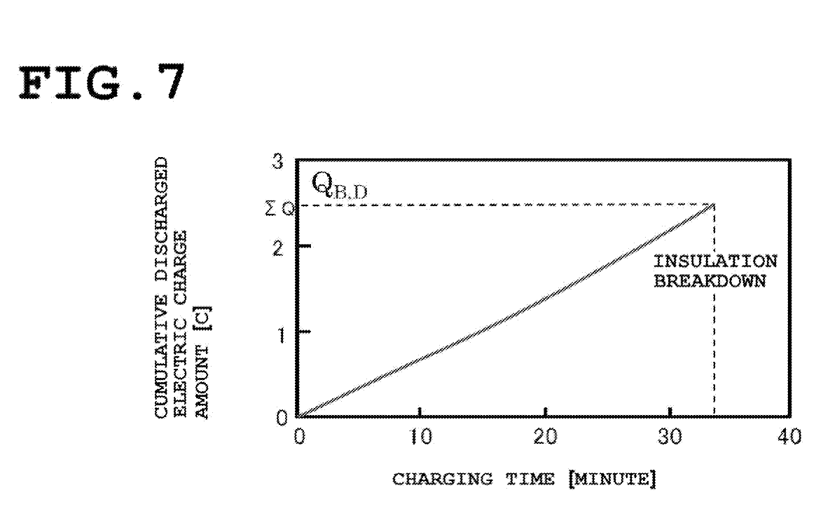

FIG. 7 is an explanatory view showing a specific example of the correlative information according to this embodiment. The figure shows an example of the total discharged electric charge amount Q_{B.D.} required in the period from start of usage of the sample 1 until the insulation breakdown occurs in the sample 1. Note that the total discharged electric charge amount Q_{B.D.} is different depending on the kind of the sample 1.

When the total discharged electric charge amount Q_{B.D.} is generated as the correlative information, thereafter the controller 4d stores and holds a generation result thereof (namely the total discharged electric charge amount Q_{B.D.}) in the database section 44 in association with the kind of the sample 1. For example, the calculated total discharged electric charge amount Q_{B.D.} is stored and held in the database section 44, in association with each of the enamel wire A, enamel wire B, . . . enamel wire Z, etc., having different material, size, and shape, etc., of the insulator.

The advance preparation step (S1) is performed through each of the above-mentioned steps (S11 to S15). When the total discharged electric charge amount Q_{B.D.} regarding the same kind of sample 1 as the sample 1 whose insulation lifetime is supposed to be estimated later, is already stored and held in the database section 44, there is no necessity for performing the advance preparation step (S1) again. Namely, if the correlative information already exists in the database section 44, execution of the advance preparation step (S1) may be omitted.

### (S2: Information Acquisition Step)

If there is a necessity for estimating the insulation lifetime for the sample 1 after end of the advance preparation step (S1), the estimating system of an insulation lifetime performs each step after the information acquisition step (S2).

The information acquisition step (S2) is the step of obtaining the correlative information regarding the sample 1. More specifically, this is the step of reading and acquiring the correlative information stored and held in the database section 44 for the same kind of sample as the sample 1 for testing, namely reading and acquiring the information for specifying the total discharged electric charge amount Q_{B.D.} until the insulation breakdown occurs in the sample 1, from the database section 44.

Read of the total discharged electric charge amount Q_{B.D.} in the information acquisition step (S2) is performed by the controller 4d that functions as the information acquisition section 45.

Note that the information acquisition step (S2) may be completed by the time point when the lifetime estimation step (S4) is started, and may be performed in parallel to the electric charge amount detection step (S3).

### (S3: Electric Charge Amount Detection Step)

The electric charge amount detection step (S3) is the step of generating the partial discharge in the sample 1 tested in the stage of estimating the insulation lifetime, and detecting the discharged electric charge amount per unit time caused by the partial discharge actually generated in the sample 1.

### (Circuit Structure of the Estimating System of an Insulation Lifetime)

In a specific circuit structure of the estimating system of an insulation lifetime for performing the electric charge amount detection step (S3), the circuit structure similar to the one described in the advance preparation step (S1) may be used. In this case, the controller 4d functions as the lifetime estimation section 46.

However, in the electric charge amount detection step (S3), the discharged electric charge amount per unit time may be detected, and there is no necessity for calculating the cumulative value of the discharged electric charge amount like the case of the advance preparation step (S1). Therefore, in the circuit structure used in the electric charge amount detection step (S3), the data loggers 4a, 4b are not required to be configured so that a plurality of them are used together, and may be configured so that only a single number may be operated.

### (Processing Procedure of the Electric Charge Amount Detection Step)

Subsequently, the processing procedure of the electric charge amount detection step (S3) is described.

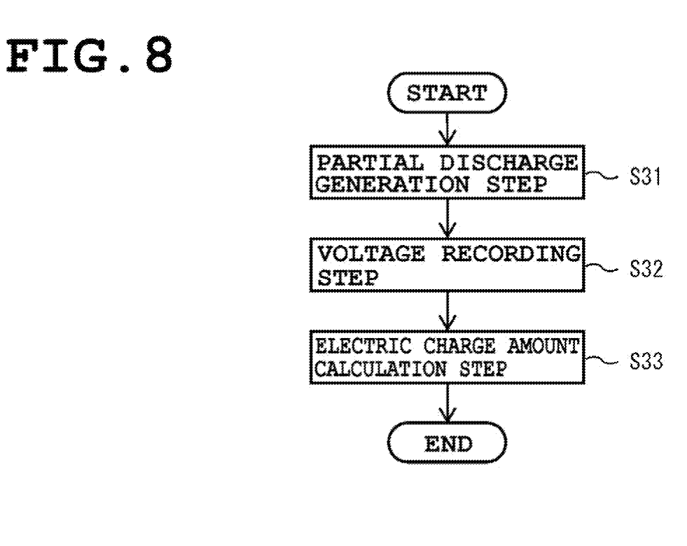

FIG. 8 is a flowchart showing the outline of the processing procedure of the electric charge amount detection step according to this embodiment.

The electric charge amount detection step (S3) includes the steps of partial discharge generation step (S31), voltage recording step (S32), and electric charge amount calculation step (S33) sequentially.

### (Partial Discharge Generation Step)

In the partial discharge generation step (S31), the charging section 2 applies the voltage of the sample 1 which is higher than PDIV, to the sample 1 for testing by the inverter surge pulse for example, to thereby generate the partial discharge in the sample 1. The voltage may be applied to the sample 1 by the charging section 2, for a previously set specific measurement period in an initial stage of usage of the sample 1. Here, the “initial stage of usage” is a specific measurement period elapsed from start of usage of the sample 1. However, the “initial stage of usage” is not limited thereto, and includes a stage which can be regarded as the initial stage in consideration of the whole period until the insulation breakdown occurs in the sample 1, as the term of “initial stage of usage” used here. Further, the “specific measurement period” may be the period if it is a sufficient period for detecting the discharged electric charge amount per unit time, and specifically it can be considered that 10 seconds is set as the “specific measurement period”.

### (Voltage Recording Step)

In the voltage recording step (S32), simultaneously with start of applying the voltage to the sample 1 by the charging section 2, the operations of the data loggers 4a 4b are started, to thereby start measurement and recording of the terminal voltage of the capacitor 3a. Then, the data loggers 4a, 4b are operated until at least the specific measurement period is over, to thereby measure the voltage outputted from the sample 1 and record the voltage data. At this time, it is preferable that the voltage data is recorded during the specific measurement period, and therefore switch of the operations of the data loggers 4a, 4b is not required.

When the data of the terminal voltage of the capacitor 3a is recorded, the data loggers 4a, 4b transmit the recorded data to the controller 4d in the form of waveform data.

### (Electric Charge Amount Calculation Step)

In the electric charge amount calculation step (S33), when the transmitted data is received from the data loggers 4a, 4b, the controller 4d calculates the electric charge amount remained in the capacitor 3a as the discharged electric charge amount discharged from the sample 1. Calculation of the discharged electric charge amount may be performed similarly to the case of the electric charge amount calculation step (S13) of the advance preparation step (S1).

When the discharged electric charge amount in the specific measurement period is calculated, the controller 4d divides the calculation result thereof by a time value of the specific measurement period, to thereby calculate the discharged electric charge amount ΔQs [unit: C/s]. When the discharged electric charge amount ΔQs per unit time is thus calculated, the controller 4d temporarily stores the calculation result in RAM, etc., which can be accessed by the controller 4d.

### (S4: Lifetime Estimation Step)

The lifetime estimation step (S4) performed after the information acquisition step (S2) and the electric charge amount detection step (S3), is the step of obtaining a period until the insulation breakdown occurs in sample 1 for testing from the discharged electric charge amount ΔQs per unit time detected in the electric charge amount detection step (S3), based on the correlative information obtained in the information acquisition step (S2), as an estimation result of the insulation lifetime regarding the sample 1. More specifically, in the lifetime estimation step (S4), the total discharged electric charge amount Q_{B.D} which is the correlative information, is divided by the discharged electric charge amount AQs per unit time, to thereby obtain the period until the insulation breakdown occurs in the sample 1, from start of usage of the sample 1.

Specifically, the controller 4d obtains the estimation result of the insulation lifetime using the following formula (2).

Ts=Q_{B.D}/ΔQs (2)

In formula (2), Is indicates the period [unit: s] from start of usage of the sample 1 until the insulation breakdown occurs, and Q_{B.D} indicates the total discharged electric charge amount [unit: C] that causes the insulation breakdown to occur in the sample 1, and ΔQs indicates the discharged electric charge amount [unit: C/s] per unit time in the initial stage of usage of the sample 1.

Information regarding the calculation result of the period Is thus obtained, is outputted from the information output section 5 as the estimation result of the insulation lifetime regarding the sample 1 for testing. An aspect of information output by the information output section 5 at this time, is not particularly limited, and may be suitably set (for example utilizing a chart or a graph, etc.)

### 3. Other Embodiment

Other embodiment of the present invention will be described next. Wherein, only a different point from the above-mentioned embodiment is described and explanation for the same matter is omitted.

This embodiment is different from the above-mentioned embodiment, in the advance preparation step (S1), the correlative information generation step (S15), the partial discharge generation step (S31) in the electric charge amount detection step (S3), and the lifetime estimation step (S4).

### (Correlative Information Generation Step)

In the correlative information generation step (S15) in this embodiment, the controller 4d generates the correlative information based on the discharged electric charge amount calculated in the electric charge amount calculation step (S13) and the total discharged electric charge amount calculated in the cumulative electric charge amount calculation step (S14). Specifically, the controller 4d generates the information regarding an aging variation characteristic of the discharged electric charge amount until the insulation breakdown occurs, as a specific example of the correlative information. Here, the “aging variation characteristic” is the characteristic of showing how the result of detecting the discharged electric charge amount is varied over time.

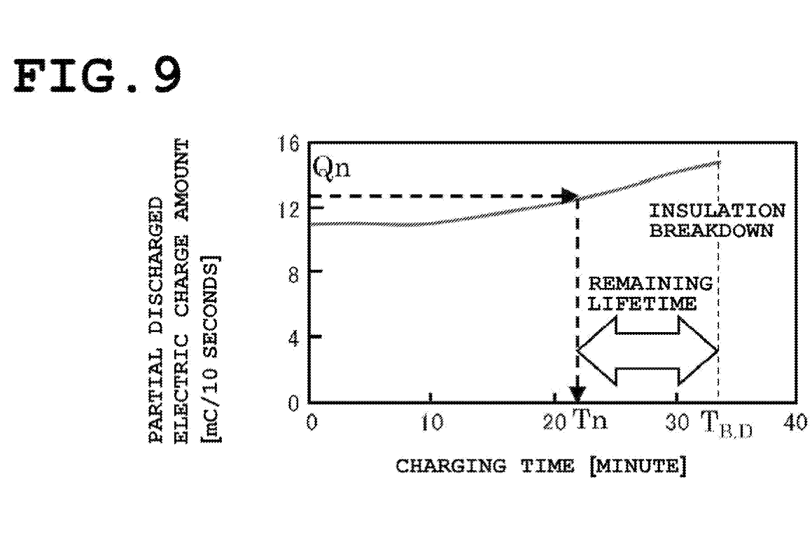

FIG. 9 is an explanatory view showing a specific example of the correlative information according to this embodiment.

The figure shows an example of the aging variation characteristic in which the discharged electric charge amount that causes the insulation breakdown calculated in the electric charge amount calculation step (S13), is converted to the discharged electric charge amount per unit time (for example 10 seconds), and thereafter each time-series [unit: min] discharged electric charge amount per unit time (unit: mC/10a] is arranged and shown in the period until the insulation breakdown occurs in the sample 1 (namely, in the period until the discharged electric charge amount reaches the total discharged electric charge amount). Note that the aging variation characteristic of the discharged electric charge amount is different depending on the kind of the sample 1.

When the correlative information is thus generated, thereafter, the controller 4d stores and holds the generation result (namely the aging variation characteristic of the discharged electric charge amount) in the database section 44 in association with the kind of the sample 1. At this time, the database section 44 stores the information in the form of specifying the relation between the discharged electric charge amount and the elapsed time of a charging time (for example, in the form of a two-dimensional chart or a function). Further, the stored information is read by the controller 4d in the information acquisition step (S2).

### (Partial Discharge Generation Step)

In the partial discharge generation step (S31) in this embodiment, the partial discharge is generated by applying voltage to the sample 1 for testing by the charging section 2. However, the voltage is not necessarily requited to be applied in the initial stage of usage of the sample 1. Namely, in this embodiment, even in a case of the sample 1 passed through a certain charging time, it can be an object for estimating the insulation lifetime.

Further, in the partial discharge generation step (S31) in this embodiment, the voltage is applied to the sample 1 for a specific measurement period, and this specific measurement period corresponds to the specific unit time used for the conversion performed in the above-mentioned correlative information generation step (S15).

### (Lifetime Estimation Step)

In the lifetime estimation step (S4) in this embodiment, the controller 4d estimates the insulation lifetime regarding the sample 1 for testing as follows. Namely, since the discharged electric charge amount Qn in the sample 1 after elapse of a certain charging time is detected in the electric charge amount detection step (S3) before the lifetime estimation step (S4), the controller 4d obtains the charging time Tn corresponding to the discharged electric charge amount Qn by comparing the discharged electric charge amount Qn and the correlative information (namely the aging variation characteristic of the discharged electric charge amount) read in the information acquisition step (S2). When the charging time Tn is obtained, the controller 4d specifies the charging time T_{B.D} required for causing the insulation breakdown to occur in the sample 1, and obtains a remained term from the charging time Tn to the charging time T_{B.D.} Then, the remained term obtained by the controller 4d is defined as the estimation result of the insulation lifetime regarding the sample 1.

Specifically, the controller 4d obtains the estimation result of the insulation lifetime using the following formula (3).

Tr=T_{B.D}−Tn (3)

Wherein in formula (3), Tr indicates the remained term [unit: min] from a time point when the electric charge amount is detected until the insulation breakdown occurs in the sample 1 for testing, and T_{B.D} indicates the charging time [unit: min] required for causing the insulation breakdown to occur in the sample 1, and Tn indicates a time-elapsed charging time [unit: min] estimated from the aging variation characteristic of the discharged electric charge amount regarding the sample 1 and the detected electric charge amount Qn of the sample 1.

Information regarding the calculation result of the remained term Tr thus obtained is outputted from the information output section 5 as the estimation result of the insulation lifetime regarding the sample 1 for testing. An aspect of information output by the information output section 5 at this time, is not particularly limited, and may be suitably set (for example utilizing a chart or a graph, etc.)

### 4. Effect of Each Embodiment

According to the above-mentioned each embodiment, one or a plurality of effects shown below are exhibited.

(1) In each embodiment, the discharged electric charge amount of the partial discharge having the correlation with the insulation breakdown of the insulator, is used as the index of estimating the insulation lifetime, to thereby estimate the insulation lifetime using not the applied voltage but the actually generated discharged electric charge amount as a reference. Namely, the insulation lifetime regarding the sample 1 for testing is estimated using a discharge energy required for causing the insulation breakdown to occur, as the index. Therefore, in each embodiment, the insulation lifetime of the sample 1 can be estimated in consideration of the influence of the rise time of variously different waveform of the voltage applied to the sample 1, irrespective of the condition of the waveform of the voltage applied to the sample 1 for testing.

Thus, according to each embodiment, reliability in the estimation result of the insulation lifetime can be improved, compared with a conventional estimation of the insulation lifetime utilizing the V-t characteristic. Specifically, for example PDIV receives the influence of a pulse rise time under the inverter surge pulse voltage, and therefore the insulation lifetime cannot be discussed only by the peak value of the applied voltage. Therefore, the result with sufficient reliability cannot be necessarily obtained by the conventional estimation of the insulation lifetime utilizing the V-t characteristic. However, in a case of estimating the insulation lifetime described in each embodiment, the insulation lifetime can be estimated while reflecting the condition of the actual waveform of the applied voltage and therefore the reliability in the estimation result of the insulation lifetime can be improved compared with conventional.

Further, according to each embodiment, the estimation of the insulation lifetime can be efficiently performed, compared with the conventional case of utilizing the V-t characteristic. Specifically, for example in the conventional estimation of the insulation lifetime utilizing the V-t characteristic, if the applied voltage waveform condition in actual use is changed, the V-t test is required to be conducted every time the condition is changed, or the V-t characteristic is required to be converted by PDIV ratio in consideration of the application of the inverter surge voltage, and therefore the estimation of the lifetime is not efficient accordingly. However, in the case of estimating the insulation lifetime described in each embodiment, the insulation lifetime can be estimated while reflecting the actual applied voltage waveform condition, and therefore the insulation lifetime can be efficiently estimated compared with the conventional estimation.

(2) In each embodiment, upon estimation of the insulation lifetime, the discharged electric charge amount caused by the partial discharge generated in sample 1, is directly detected utilizing a measurement of a discharge current/voltage waveform, etc., by a residual electric charge method using a serial capacitor, a differential detection method using high frequency CT, and a detection impedance method for example. Namely, a discharge energy generated by the partial discharge in sample 1 is directly detected.

In this point as well, the insulation lifetime can be efficiently estimated while improving the reliability.

For example, the discharged electric charge amount can also be calculated from a discharge current waveform obtained by the V-t test. However, in order to calculate the electric charge amount from the discharge current waveform (for example raw waveform data obtained by an oscilloscope) obtained by the V-t test, the discharge current waveform with steep rise is required to be integrated by a sample rate of nano-second (ns). Therefore, in order to calculate the electric charge amount, enormous numbers of data are required. If the period is prolonged for causing the insulation breakdown to occur in the sample 1, the numbers of data required for calculating the electric charge amount is further increased by the prolonged portion. As a result, time is required for data processing, thus involving a problem that efficiency is reduced and a storage area for storing the enormous data is required. In this point, according to each embodiment, the discharged electric charge amount is directly detected, and therefore the insulation lifetime can be efficiently estimated.

Further, for example, when the cumulative electric charge amount causing the insulation breakdown to occur in sample 1 is calculated, there is a risk of causing an acquisition leakage of data to occur if the enormous numbers of data are required to be processed. Moreover, when the electric charge amount is calculated from the raw waveform data obtained by the oscilloscope, etc., there is a possibility of dropping of data depending on the performance, etc., of the oscilloscope. Therefore, there is a risk of reducing the precision in estimating the insulation lifetime regarding sample 1, resulting in damaging the reliability in the estimation result of the insulation lifetime. In this point, since the discharged electric charge amount is directly detected in each embodiment, dropping of data does not occur and the reliability in estimating the insulation lifetime can be improved.

(3) According to an embodiment described above, the insulation lifetime is estimated regarding sample 1 by detecting the discharged electric charge amount per unit time caused by the partial discharge generated in the initial stage of usage of the sample 1, based on the total discharged electric charge amount Q_{B.D} as the correlative information.

Therefore, according to an embodiment, even when the discharged electric charge amount per unit time is changed depending on the applied voltage waveform condition, the insulation lifetime of the sample 1 can be estimated in consideration of the influence of the discharged electric charge amount per unit time generated in the sample 1.

In addition, according to an embodiment, the insulation lifetime of sample 1 is estimated from the discharged electric charge amount in the initial stage of usage of the sample 1. Therefore, according to an embodiment, the insulation lifetime can be estimated so as to appropriately evaluate the selection of an electric insulation product (for example, coils) and the lifetime of the product, and an appropriate specification can be efficiently determined when the product is developed and designed. Moreover, development into insulation design at a development side of the product is easier than the conventional V-t characteristic, thus improving the reliability in estimating the insulation lifetime.

(4) In the abovementioned other embodiment, the discharged electric charge amount caused by the partial discharge generated in sample 1 after elapse of a certain charging time is detected based on the aging variation characteristic of the discharged electric charge amount as the correlative information, to thereby estimate a remaining lifetime term of the sample 1.

Therefore, according to other embodiment, even in a case of the sample 1 after elapse of a certain charging time and even if the charging time is unknown, the sample 1 can be an object whose insulation lifetime should be estimated. In addition, even in this case, similarly to the case of an embodiment, the insulation lifetime can be efficiently estimated while improving the reliability in the estimation result of the insulation lifetime.

(5) In each embodiment, the correlative information is previously generated in the advance preparation step (S1), and the generated correlative information is stored and held in the database section 44. Namely, a database is constructed in the database section 44 by the previously generated correlative information.

Therefore, according to each embodiment, when the correlative information is already stored and held in the database section 44, the advance preparation step (S1) is not required to be performed again, and therefore efficiency of estimating the insulation lifetime is thus achieved. Further, if the correlative information already exists in the database section 44, the correlative information is preferably read and acquired from the database section 44 for estimating the insulation lifetime regarding sample 1. Therefore, in this point as well, efficiency in the estimating method of the insulation lifetime is achieved.

### 5. Modified Example, Etc.

Embodiments of the present invention are described above. However, a technical scope of the present invention is not limited to abovementioned each embodiment, and can be variously modified in the scope not departing from the gist of the present invention.

The abovementioned each embodiment gives a case that the control section 4 of the estimating system of the insulation lifetime has a function as the database section 44. However, the present invention is not limited thereto, and if the information acquisition section 45 can acquire the correlative information, the database section 44 may be provided in an external different device (for example a sever device connected through a network line). This means that the estimating system of the insulation lifetime according to the present invention is not necessarily required to include the database section 44, if the correlative information can be acquired. Further, according to the estimating method of the insulation lifetime, the correlative information is already generated, and if the generated correlative information can be acquired from outside, the advance preparation step (S1) is not necessarily required to be performed.

Further, the abovementioned each embodiment gives a case that a plurality of data loggers 4a, 4b are used together in consideration of performing the advance preparation step (S1). However, the present invention is not limited thereto, and if the advance preparation step (S1) is not required, only a single data logger may be operated. Further, when the advance preparation step (S1) is performed, three or more data loggers may also be provided. In this case, an operation order, etc., of each data logger is not particularly limited, and any one of the data loggers may be started to be operated, if the voltage added on the capacitor 3a can be continuously measured and recorded.

### PREFERRED ASPECT OF THE PRESENT INVENTION

Preferred aspects of the present invention will be described below.

According to an aspect of the present invention, there is provided an estimating method of an insulation lifetime for estimating an insulation lifetime in a sample constituted by including a conductor and an insulator, including:

an information acquisition step of obtaining correlative information regarding a discharged electric charge amount caused by a partial discharge in the sample and an insulation breakdown of the sample;

an electric charge amount detection step of generating a partial discharge in the sample in the stage of estimating the insulation lifetime and detecting a discharged electric charge amount caused by the partial discharge; and

a lifetime estimation step of obtaining a period until the insulation breakdown occurs in the sample, from the discharged electric charge amount detected in the electric charge amount detection step, based on the correlative information obtained in the information acquisition step, as a estimation result of the insulation lifetime.

Preferably, there is provided the estimating method of an insulation lifetime, wherein in the information acquisition step, information for specifying a total discharged electric charge amount causing an insulation breakdown to occur in the sample is acquired as the correlative information, and in the electric charge amount detection step, a discharged electric charge amount per unit time caused by a partial discharge generated in the sample is detected, and in the lifetime estimation step, a period from start of usage of the sample until the insulation breakdown occurs in the sample is obtained by dividing the total discharged electric charge amount by the discharged electric charge amount per unit time.

Preferably, there is provided the estimating method of an insulation lifetime, wherein in the information acquisition step, information for specifying an aging variation characteristic of a discharged electric charge amount caused by a partial discharge in the sample from start of usage of the sample until the insulation breakdown occurs in the sample is acquired, and in the electric charge amount detection step, a discharged electric charge amount caused by a partial discharge generated in the sample is detected, and in the lifetime estimation step, a remained term until the insulation breakdown occurs in the sample is obtained by comparing a detection result obtained in the electric charge amount detection step, with the aging variation characteristic.

Preferably, there is provided the estimating method of an insulation lifetime, including an advance preparation step before the information acquisition step, which is the step of continuously detecting a discharged electric charge amount caused by a partial discharge in the sample from start of usage of the sample until an insulation breakdown occurs in the sample, and generating the correlative information from a detection result thereof, and storing and holing the correlative information, wherein in the information acquisition step, the correlative information is acquired by reading the correlative information stored and held in the advance preparation step.

According to other aspect, there is provided an estimating system of an insulation lifetime for estimating an insulation lifetime in a sample constituted by including a conductor and an insulator, including:

an information acquisition section configured to obtain correlative information regarding a discharged electric charge amount caused by a partial discharge in the sample and an insulation breakdown of the sample;

an electric charge amount detection section configured to detect a discharged electric charge amount caused by a partial discharge by generating the partial discharge in the sample in the stage of estimating the insulation lifetime; and

a lifetime estimation section configured to obtain a period until an insulation breakdown occurs in the sample, from the discharged electric charge amount detected by the electric charge amount detection section, based on the correlative information obtained by the information acquisition section, and obtain a estimation result of the insulation lifetime.

Preferably, there is provided the estimating system of an insulation lifetime, including a database section configured to store and hold the correlative information, wherein the information acquisition section is configured to acquire the correlative information by reading the correlative information stored and held in the database section.

Preferably, there is provided the estimating system of an insulation lifetime, including an information generation section configured to continuously detect a discharged electric charge amount caused by a partial discharge in the sample from start of usage of the sample until an insulation breakdown occurs in the sample, and generate the correlative information from a detection result thereof, and store and hold the correlative information in the database section.

What is claimed is:

1. An estimating method of an insulation lifetime for estimating an insulation lifetime in a sample constituted by including a conductor and an insulator, comprising:
an information acquisition step of obtaining correlative information regarding a discharged electric charge amount caused by a partial discharge in the sample and an insulation breakdown of the sample;
an electric charge amount detection step of generating a partial discharge in the sample in the stage of estimating the insulation lifetime and detecting a discharged electric charge amount caused by the partial discharge; and
a lifetime estimation step of obtaining a period until the insulation breakdown occurs in the sample, from the discharged electric charge amount detected in the electric charge amount detection step, based on the correlative information obtained in the information acquisition step, as a estimation result of the insulation lifetime.

2. The estimating method of an insulation lifetime according to claim 1, wherein in the information acquisition step, information for specifying a total discharged electric charge amount causing an insulation breakdown to occur in the sample is acquired as the correlative information, and in the electric charge amount detection step, a discharged electric charge amount per unit time caused by a partial discharge generated in the sample is detected, and in the lifetime estimation step, a period from start of usage of the sample until the insulation breakdown occurs in the sample is obtained by dividing the total discharged electric charge amount by the discharged electric charge amount per unit time.

3. The estimating method of an insulation lifetime according to claim 1, wherein in the information acquisition step, information for specifying an aging variation characteristic of a discharged electric charge amount caused by a partial discharge in the sample from start of usage of the sample until the insulation breakdown occurs in the sample is acquired, and in the electric charge amount detection step, a discharged electric charge amount caused by a partial discharge generated in the sample is detected, and in the lifetime estimation step, a remained term until the insulation breakdown occurs in the sample is obtained by comparing a detection result obtained in the electric charge amount detection step, with the aging variation characteristic.

4. The estimating method of an insulation lifetime according to claim 1, comprising an advance preparation step before the information acquisition step, which is the step of continuously detecting a discharged electric charge amount caused by a partial discharge in the sample from start of usage of the sample until an insulation breakdown occurs in the sample, and generating the correlative information from a detection result thereof, and storing and holing the correlative information, wherein in the information acquisition step, the correlative information is acquired by reading the correlative information stored and held in the advance preparation step.

5. An estimating system of an insulation lifetime for estimating an insulation lifetime in a sample constituted by including a conductor and an insulator, comprising:
an information acquisition section configured to obtain correlative information regarding a discharged electric charge amount caused by a partial discharge in the sample and an insulation breakdown of the sample;
an electric charge amount detection section configured to detect a discharged electric charge amount caused by a partial discharge by generating the partial discharge in the sample in the stage of estimating the insulation lifetime; and
a lifetime estimation section configured to obtain a period until an insulation breakdown occurs in the sample, from the discharged electric charge amount detected by the electric charge amount detection section, based on the correlative information obtained by the information acquisition section, and obtain a estimation result of the insulation lifetime.

6. The estimating system of an insulation lifetime, comprising a database section configured to store and hold the correlative information, wherein the information acquisition section is configured to acquire the correlative information by reading the correlative information stored and held in the database section.

7. The estimating system of an insulation lifetime according to claim 6, comprising an information generation section configured to continuously detect a discharged electric charge amount caused by a partial discharge in the sample from start of usage of the sample until an insulation breakdown occurs in the sample, and generate the correlative information from a detection result thereof, and store and hold the correlative information in the database section.
